(19) United States
(12) Patent Application Publication
(10) Pub. No.: US 2026/0372069 A1
(43) Pub. Date: Nov. 19, 2026

(54) SEMICONDUCTOR STRUCTURE HAVING THERMAL SENSOR AND MANUFACTURING METHOD THEREOF

(71) Applicant: Taiwan Semiconductor Manufacturing Company, Ltd., Hsinchu (TW)

(72) Inventors: Isha Datye, Hsinchu (TW); Sam Vaziri, San Jose, CA (US); Xinyu BAO, Fremont, CA (US)

(73) Assignee: Taiwan Semiconductor Manufacturing Company, Ltd., Hsinchu (TW)

(21) Appl. No.: 19/752,696

(22) Filed: Jul. 24, 2026

Related U.S. Application Data
(63) Continuation of application No. 18/403,723, filed on Jan. 4, 2024.
(60) Provisional application No. 63/611,203, filed on Dec. 17, 2023.

(51) Int. Cl. H10W 40/00; H10W 70/63; H10W 72/00; H10W 90/00

(52) U.S. Cl. CPC H10W 40/00; H10W 70/635; H10W 72/01351; H10W 90/734

(57) ABSTRACT

A manufacturing method of a semiconductor structure includes: forming a first interconnect structure over a first semiconductor substrate through back-end-of-line (BEOL) processes; forming thermal sensors over the first semiconductor substrate and in the first interconnect structure, where the thermal sensors are formed of materials compatible with the BEOL processes; and forming a first bonding structure over the first interconnect structure, wherein the thermal sensors are electrically isolated from conductive features of the first interconnect structure and the first bonding structure.

### CROSS-REFERENCE TO RELATED APPLICATION

This application is a continuation application of and claims the priority benefit of a prior application Ser. No. 18/403,723, filed on Jan. 4, 2024, now pending. The prior application Ser. No. 18/403,723 claims the priority benefit of U.S. provisional application Ser. No. 63/611,203, filed on Dec. 17, 2023. The entirety of the above-mentioned patent application is hereby incorporated by reference herein and made a part of this specification.

### BACKGROUND

The semiconductor industry has experienced rapid growth due to continuous improvement in integration density of various devices. For the most part, this improvement in integration density has come from successive reductions in minimum feature size, which allows more devices to be integrated into a given area. Technological advances in integrated circuit (IC) design have produced generations of ICs where each generation has smaller and more complex circuit designs than the previous generation. The high device density may introduce heat that may cause performance deterioration. To monitor and control heat generation, thermal sensors may be needed. Although existing semiconductor structures with thermal sensors are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 3-6 illustrate schematic cross-sectional views of intermediate stages in the manufacturing of a semiconductor structure having thermal sensors, in accordance with some embodiments.

FIG. 2B illustrates a schematic top-down view of the structure in FIG. 2A to show the locations of the thermal sensors and the regions to be monitored, in accordance with some embodiments.

FIGS. 2C and 2D illustrate fragmentary views of different types of a thermal sensor, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The high device density brought about by advanced transistors may introduce heat, and accumulation of heat in a semiconductor structure may cause performance deterioration. Embodiments discussed herein are to provide a semiconductor structure including thermal sensor(s), where the thermal sensor(s) may be configured to monitor and/or measure temperature variations in the semiconductor structure. The thermal sensor(s) may be fabricated by back-end-of-line (BEOL) processes and may be formed of materials which are compatible with BEOL processes. It should be noted that throughout the description, the terms “thermal sensor” and “temperature sensor” are interchangeably used.

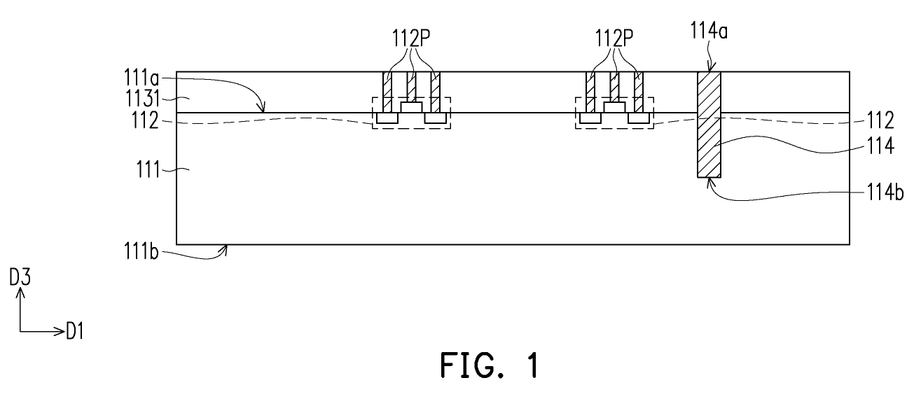

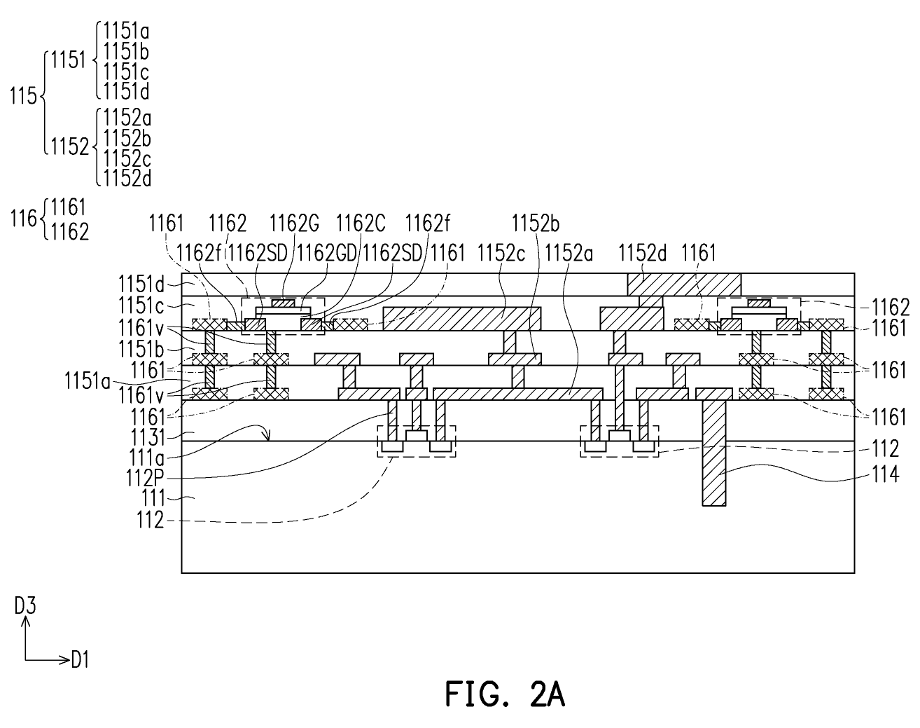

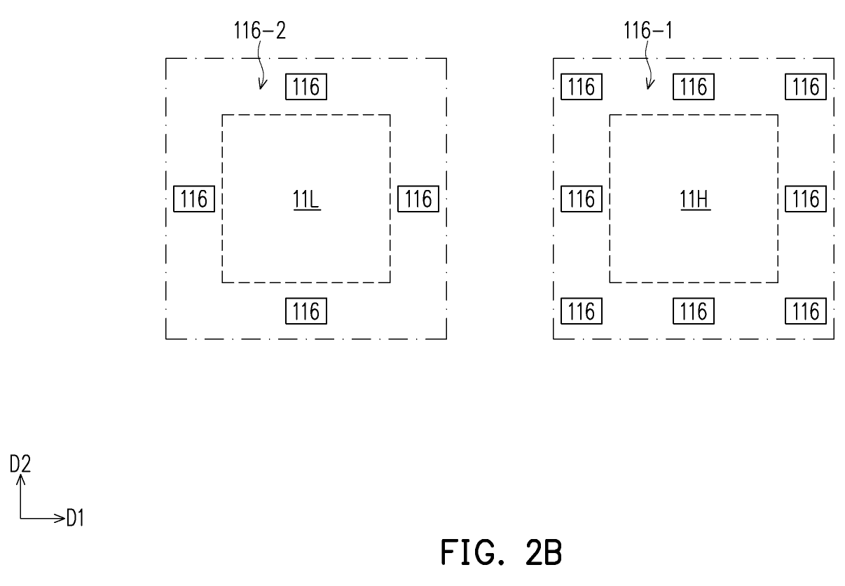

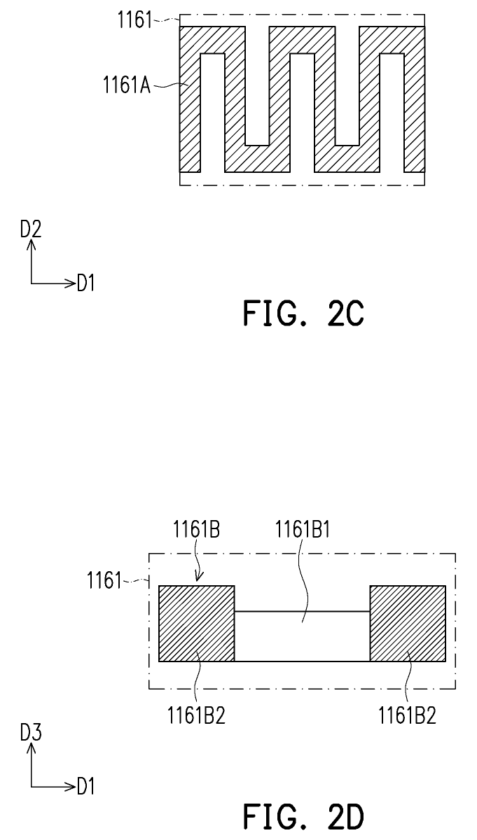

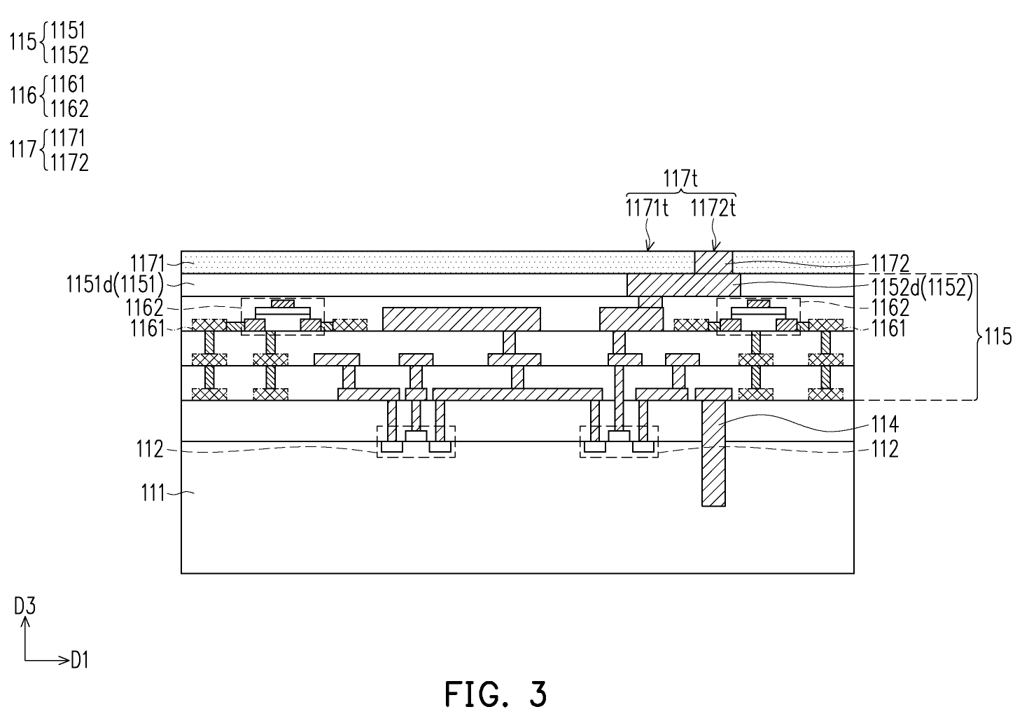

FIGS. 1, 2A, 3-6 illustrate schematic cross-sectional views of intermediate stages in the manufacturing of a semiconductor structure having thermal sensors, FIG. 2B illustrates a schematic top-down view of the structure in FIG. 2A to show the locations of the thermal sensors and the regions to be monitored, and FIGS. 2C and 2D illustrate fragmentary views of different types of a thermal sensor, in accordance with some embodiments. For clarity of illustrations, in the drawings are illustrated the orthogonal axes of the coordinate system according to which the views are oriented. For example, FIGS. 1, 2A, 2D, 3-6 are cross-sectional views along the D1-D3 plane (e.g., X-Z plane or Y-Z plane), where the direction D1 is substantially perpendicular to the direction D3. FIGS. 2B and 2C may be top-down views along the D1-D2 plane (e.g., X-Y plane), where the direction D1 is substantially perpendicular to the direction D2. Moreover, the manufacturing method described below is merely an example and is not intended to limit the present disclosure. Additional steps may be provided before, during and after the manufacturing method and some steps described can be replaced, eliminated, or moved around for additional embodiments of the method. Not all steps are described herein in detail for reasons of simplicity. Additionally, throughout the descriptions and across different embodiments, like reference numerals denote like features with similar structures and compositions, unless otherwise excepted.

Referring to FIG. 1, a semiconductor substrate 111 is provided. For example, the semiconductor substrate 111 is in a wafer form, a chip form, a panel form, etc. The semiconductor substrate 111 may include a front side 111a (or an active surface) and a back side 111b opposite to the front side 111a. The semiconductor substrate 111 may include one or more semiconductor material(s), such as silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, one or more first device(s) 112 may be formed at the front side 111a of the semiconductor substrate 111. The first device(s) 112 may be active devices (e.g., transistors, diodes, etc.), passive devices (e.g., capacitors, resistors, inductors, etc.), combinations thereof, and/or the like. The first devices 112 may be or include high-power device(s) and/or low-power device(s). In some embodiments, the first devices 112 are formed using suitable Front-end-of-line (FEOL) process and may be referred to as the FEOL devices. It should be appreciated that although two first devices 112 are illustrated and represented by a transistor, the first devices 112 may have a different number and type than shown. In some embodiments, an inter-layer dielectric (ILD) layer 1131 is formed over the front side 111a of the semiconductor substrate 111 to surround and cover the first devices 112. The ILD layer 1131 may include one or more dielectric material(s) such as phospho-silicate glass (PSG), boro-silicate glass (BSG), boron-doped phospho-silicate glass (BPSG), undoped silicate glass (USG), the like, or combinations thereof. In some embodiments, conductive plugs 112P extend through the ILD layer 1131 to electrically and physically couple to the first devices 112. The conductive plugs 112P may be formed of W, Co, Ni, Cu, Ag, Au, Al, alloy, the like, or combinations thereof. For example, when the first devices 112 are transistors, the conductive plugs 112P may couple the gates and source/drain (S/D) regions of the transistors. Although shown as being formed in the same cross-section, it should be appreciated that each of the conductive plugs 112P coupled to the gates and S/D regions may be formed in different cross-sections, which may avoid shorting of the contacts. It should be noted that S/D region(s) may refer to a source or a drain, individually or collectively dependent upon the context.

With continued reference to FIG. 1, one or more through via(s) 114 may be formed in the semiconductor substrate 111 and may pass through the ILD layer 1131. For example, the through via 114 is formed by depositing one or more diffusion barrier layer(s) or isolation layer(s), depositing a seed layer, and depositing a conductive material (e.g., W, Ti, Al, Cu, any combinations thereof, and/or the like) into the trenches of the ILD layer 1131 and the underlying semiconductor substrate 111. In some embodiments, a planarization process (e.g., chemical mechanical polishing (CMP), grinding, etching, a combination thereof, etc.) is performed on the through via 114 and the ILD layer 1131 such that the through via 114 and the ILD layer 1131 are substantially leveled (or coplanar), within process variations. For example, the through via 114 includes a first end 114a substantially leveled with the ILD layer 1131 and a second end 114b opposite to the first end 114a, where the second end 114b may be buried in the semiconductor substrate 111 at this stage.

Referring to FIG. 2A and with reference to FIG. 1, an interconnect structure 115 may be formed over the front side 111a of the semiconductor substrate 111. For example, the interconnect structure 115 is formed on the ILD layer 1131, the through vias 114, and the conductive plugs 112P. In some embodiments, the interconnect structure 115 is formed through back-end-of-line (BEOL) processes. For example, the interconnect structure 115 includes a dielectric layer 1151 and one or more conductive layer(s) 1152 embedded in the dielectric layer 1151. The dielectric layer 1151 may include one or more dielectric material(s) such as low-k dielectric materials (e.g., PSG, BPSG, fluorosilicate glass (FSG), Spin-On-Glass, Spin-On-Polymers, silicon carbon materials, combinations thereof, etc.) or any suitable dielectric materials. In some embodiments, the dielectric layer 1151 is referred to as an inter-metal dielectric (IMD) layer. For example, the dielectric layer 1151 includes a first dielectric sublayer 1151a overlying the ILD layer 1131, a second dielectric sublayer 1151b overlying the first dielectric sublayer 1151a, a third dielectric sublayer 1151c overlying the second dielectric sublayer 1151b, and a fourth dielectric sublayer 1151d overlying the third dielectric sublayer 1151c. The first, second, third, and fourth dielectric sublayers (1151a, 1151b, 1151c, and 1151d) may include the same material or include different materials. It should be appreciated that although four dielectric sublayers are shown, the dielectric layer 1151 may include more than four dielectric sublayers or less than four dielectric sublayers, depending on circuit and product requirements.

In some embodiments, the conductive layers 1152 may each include conductive features (e.g., lines, vias, pads, etc.). The conductive vias of the conductive layers 1152 may go through the plane of adjacent sublayers and provide electrical connection between the adjacent sublayers. The conductive layers 1152 may include one or more conductive material(s) such as Ti, Cu, Ni, Ag, Au, Al, alloy, the like, or combinations thereof. For example, the conductive layers 1152 electrically interconnect the first devices 112 through the conductive plugs 112P to form an integrated circuit. The conductive layers 1152 may be electrically connected to the through vias 114. In FIG. 2A, the through via 114 is physically connected to the bottommost one of the conductive layers 1152; however, the through via 114 may extend to be connected to any level of the conductive layers 1152, depending on circuit and product requirements.

In some embodiments, the conductive layers 1152 include a first conductive sublayer 1152a formed in the first dielectric sublayer 1151a and connected to the first conductive plugs 112P and the through via 114, a second conductive sublayer 1152b formed in the second dielectric sublayer 1151b and connected to the first conductive sublayer 1152a, a third conductive sublayer 1152c formed in the third dielectric sublayer 1151c and connected to the second conductive sublayer 1152b, and a fourth conductive sublayer 1152d formed in the fourth dielectric sublayer 1151d and connected to the third conductive sublayer 1152c. In some embodiments, the dimension and line/spacing of the fourth conductive sublayer 1152dare greater than those of the third conductive sublayer 1152c, the dimension and line/spacing of the third conductive sublayer 1152c are greater than those of the second conductive sublayer 1152b, and the dimension and line/spacing of the second conductive sublayer 1152bare greater than those of the first conductive sublayer 1152a. It should be appreciated that although four conductive sublayers are shown, the conductive layers 1152 may include more than four conductive sublayers or less than four conductive sublayers, depending on circuit and product requirements.

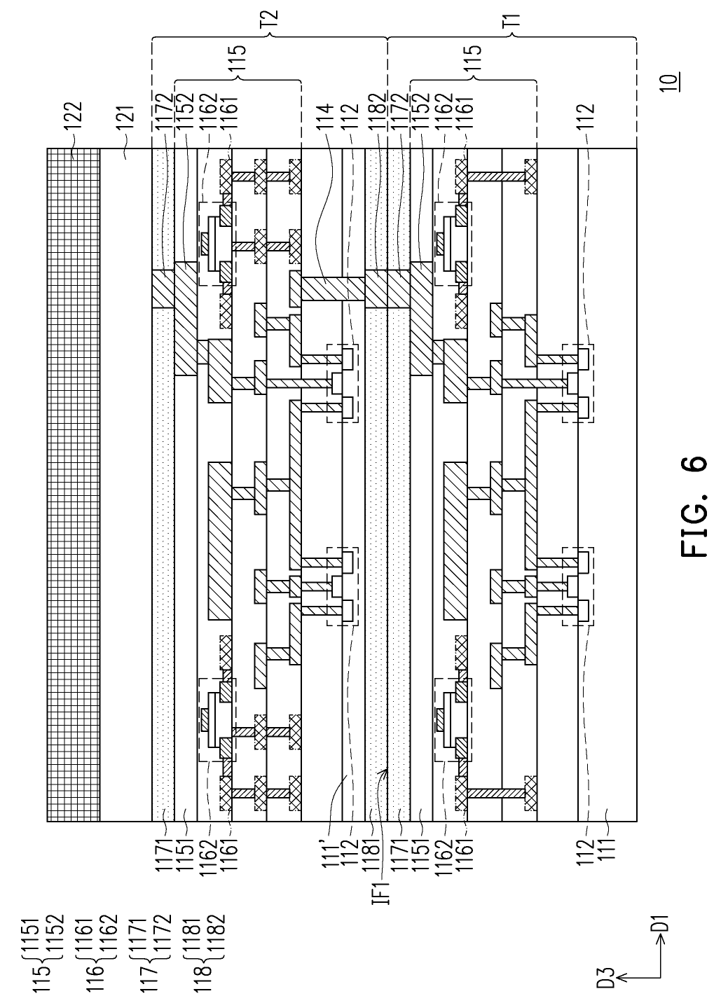

With continued reference to FIG. 2A, one or more thermal sensing device (also called a thermal/temperature sensor) 116 may be embedded in the interconnect structure 115. The thermal sensing device 116 may be electrically isolated from the conductive layer 1152 and may be used to monitor temperature of one or more devices/regions/paths in the resulting semiconductor structure (see FIG. 6). In some embodiments, material(s) and forming methods of the thermal sensing devices 116 are compatible with BEOL processes. For example, the thermal sensing devices 116 are built by the BEOL process. The thermal sensing device 116 integrated into the interconnect structure 115 may be configured to monitor or sense the temperature change or temperature variation in the resulting semiconductor structure (see FIG. 6). In some embodiments, when the temperature of the devices/regions/paths exceeds predetermined thresholds, the thermal sensing device 116 may alert a circuitry to slow down (or shut down) the corresponding device(s) to reduce power consumption and thus reduce the temperature so that overheat that can cause failure to the devices may be prevented. Dynamic power control from the circuitry may prevent device degradation or failure from high temperature. For example, a feedback circuit (not individually shown) is connected to the thermal sensing device 116 and configured to dynamically control power input of the resulting semiconductor structure. In response to the sensed/measured temperature, an adjustment to the circuit operation may be made. For example, making the adjustment to the circuit operation includes adjusting one or more operating parameters (e.g., reducing a voltage, current, or power level, etc.) or performing one or more actions (e.g., entering a reduced power mode or triggering an alert, etc.) to reduce or avoid an overheating condition, thereby enhancing performance and reliability of the resulting semiconductor structure.

With continued reference to FIG. 2A, the respective thermal sensing device 116 may include one or more thermal sensing component(s) 1161 embedded in the interconnect structure 115. The respective thermal sensing component 1161 may be surrounded and covered by the dielectric layer 1151. The thermal sensing component(s) 1161 may be disposed alongside the conductive layer(s) 1152. In some embodiments, the interconnect structure 115 includes a pattern-dense region and a pattern-sparse region, where the pattern-sparse region may have lower density (or wider space between conductive features) of the conductive layer 1152 than the pattern-dense region. The thermal sensing components 1161 may be disposed on the pattern-sparse region of the interconnect structure 115. In some embodiments where multiple thermal sensing components 1161 are disposed on different sublayers of the dielectric layer 1151, one or more conductive vias 1161v may go through the plane of adjacent sublayers and provide electrical connection between the thermal sensing components 1161 disposed on the adjacent sublayers. It should be appreciated that although the thermal sensing components 1161 are disposed on each sublayer of the dielectric layer 1151, the thermal sensing components 1161 may have a different number and arrangement than shown. The thermal sensing component 1161 may be or include a sensing circuit or any type of sensing device/element. The thermal sensing component 1161 will be described in more detail with reference to FIGS. 2C-2D.

Still referring to FIG. 2A, the respective thermal sensing device 116 may include one or more second device(s) 1162 embedded in the interconnect structure 115. For example, the thermal sensing components 1161 are electrically coupled to the second devices 1162 and electrically isolated from the first devices 112. In some embodiments, the second devices 1162 are control devices (e.g., transistors) which are included in a control circuit, where the control circuit electrically coupled to the thermal sensing components 1161 may be configured to receive voltages and generate control signals. In some embodiments, the respective second device (e.g., transistor) 1162 is used in the thermal sensor by using the transistor’s temperature-varying threshold voltage. For example, the respective second device 1162 is surrounded and covered by the dielectric layer 1151. The second device(s) 1162 may be disposed alongside the conductive layer(s) 1152 and the thermal sensing component(s) 1161. For example, the second devices 1162 and the topmost one of the thermal sensing components 1161 are disposed side-by-side and electrically connected through conductive features 1162f (e.g., conductive lines, conductive pads, conductive vias, a combination thereof, etc.). In some embodiments, material(s) and forming methods of the second devices 1162 and the thermal sensing components 1161 are compatible with BEOL processes. For example, the second devices 1162 and the thermal sensing components 1161 are built by the BEOL process. The second devices 1162 and the thermal sensing components 1161 may be viewed as BEOL devices/components.

In some embodiments, the respective second device 1162 (represented by a transistor) includes a gate electrode 1162G, S/D contacts 1162SD, a channel layer 1162C disposed below the gate electrode 1162G and laterally between the S/D contacts 1162SD, and a gate dielectric layer 1162GD vertically interposed between the gate electrode 1162G and the channel layer 1162C. For example, a material of the channel layer 1162C includes metal oxide (e.g., IGZO, In₂O₃, InWO, SnO, TaSnO, TiSnO, etc.), amorphous Si, poly-Si, two-dimensional (2D) material (e.g., MoS₂, WS₂, MoSe₂, WSe₂, MoTe₂, etc.), or any suitable channel material which is compatible with BEOL processes. In some embodiments where the second device 1162 is a 2D material-based transistor, the channel layer 1162C is formed of one or more 2D material(s) and may be deposited by metal-organic chemical vapor deposition (MOCVD) at low temperature (e.g., less than 400°C or the like). In some embodiments, the channel layer 1162C is formed of one or more metal oxide material(s) and/or poly-Si, and may be deposited by sputtering or any suitable deposition process. The gate electrode 1162G and the S/D contacts 1162SD may include one or more conductive material(s) such as Co, W, Cu, Ti, Ta, Al, Zr, Hf, a combination thereof, or other suitable metallic materials. In some embodiments, the gate electrode 1162G and the S/D contacts 1162SD are formed by sputtering or any suitable deposition process. The gate dielectric layer 1162GD may include silicon oxide, silicon nitride, silicon oxynitride, high-k dielectrics, or a combination thereof, and may be formed by sputtering or any suitable deposition process. It should be noted that although two second devices 1162 are illustrated and represented by a transistor, the second devices 1162 may have a different number and type than shown.

In alternative embodiments, the second devices 1162 are omitted, and a portion of the first devices 112 (e.g., transistors) formed through FEOL processes is included in the thermal sensing devices 116 to act as control transistors. For example, the portion of the first devices 112 is disposed below the bottommost one of the thermal sensing components 1161 and electrically connected to the bottommost one of the thermal sensing components 1161 through conductive features (not shown; e.g., conductive lines, conductive pads, conductive vias, a combination thereof, etc.). Although the second devices 1162 are represented by transistors, in some other embodiments, the second devices 1162 are diodes or any other control devices that their operation depends on temperature.

Referring to FIG. 2B and with reference to FIG. 2A, the thermal sensing devices 116 may be close, and thermally coupled, enough to the devices/regions/paths to be monitored/sensed. In some embodiments, a first set 116-1 of the thermal sensing devices 116 is arranged in a denser arrangement than a second set 116-2 of the thermal sensing devices 116, in a given area. For example, the first set 116-1 of the thermal sensing devices 116 having smaller spacing between adjacent thermal sensing devices 116 is disposed in proximity to a first region 11H. In some embodiments, one or more high-power device(s) may be formed in the first region 11H, and the first region 11H may be a higher-temperature region in the resulting semiconductor structure. In some embodiments, the first region 11H is a region having a sharp local temperature peak (referred to as a hot spot) or any region/path having higher thermal bottleneck which needs heater control. The first region 11H may be a hot spot region. The region/path having thermal bottleneck may be the region/path where heat flow is more restricted than other region/path in the resulting semiconductor structure. The first set 116-1 of the thermal sensing devices 116 may be arranged in a denser arrangement around the first region 11H to provide the controller with temperature feedback for heater control. In some embodiments, the first set 116-1 of the thermal sensing devices 116 arranged in a denser manner may be disposed in proximity to the subsequently-formed first bonding structure 117 (see FIG. 3).

In some embodiments, the second set 116-2 of the thermal sensing devices 116 has larger spacing between adjacent thermal sensing devices 116 and may be distributed in a sparser arrangement than the first set 116-1 of the thermal sensing devices 116. The second set 116-2 of the thermal sensing devices 116 may be disposed in proximity to a second region 11L. In some embodiments, one or more lower-power device(s) may be formed in the second region 11L, and the second region 11L may be a lower-temperature region in the resulting semiconductor structure. The high-power devices may consume a relatively high amount of power, and hence generate a relatively large amount of heat, compared to the low-power devices. It should be appreciated that the number of the thermal sensing devices in the first set 116-1 and the second set 116-2 in FIG. 2B is shown for illustrative purposes, and the thermal sensing devices in the first set 116-1 and the second set 116-2 may have a different arrangement and number than shown. By arranging the thermal sensing devices 116 near specific, temperature-sensitive regions, temperature data may be better correlated to actual temperature at the site of the devices/regions/paths being monitored.

Referring to FIGS. 2C-2D and with reference with FIG. 2A, various embodiments are used in the thermal sensing components 1161. In some embodiments, the respective thermal sensing component 1161 is implemented by a resistor (e.g., metal resistor, TiN resistor, implant resistor, the like, a combination thereof, etc.) or any suitable resistive component. The resistor(s) may have a resistance value with a thermal dependency. As schematically shown in the top-down view of FIG. 2C, the resistor includes a metallization pattern 1161A meanderingly extending along the D1-D2 plane. With reference to FIGS. 2C and 2A, the metallization pattern 1161A may be physically and electrically connected to the conductive features 1162f and/or the conductive vias 1161v. The metallization pattern 1161A may be disposed alongside the conductive layer 1152 and formed by using any suitable patterning and/or deposition process. In some embodiments, the metallization pattern 1161A is formed at the fourth level (M4) or above the fourth level of the interconnect structure 115. The metallization pattern 1161A may be formed of one or more conductive material(s) such as TaN, TiN, W, Ru, a combination thereof, the like, etc. The thickness of the metallization pattern 1161A measured in the direction D3 may be in a range of about 0.1μm and about 1μm. The total length of the metallization pattern 1161A may be in a range of about 10μm and about 100μm. The width of the metallization pattern 1161A may be in a range of about 1μm and about 10μm. The total resistance of the metallization pattern 1161A may be in a range of about 1Ω and 100Ω. The metallization pattern 1161A may have other suitable values, depending on product and circuit requirements.

The temperature coefficient of resistance (TCR) for a resistor is determined by measuring the resistances over a temperature range. The metallization pattern 1161A may provide a known TCR. In some embodiments, the metallization pattern 1161A (e.g., the metal resistor) has a TCR of about 0.2-0.5%/K. In some embodiments, the thermal sensing component 1161 is formed of a material having a relatively high TCR such that a small temperature change results in a large resistance change. However, a material for the resistor needs not necessarily have a material with a high TCR. If the TCR of a given material is known/repeatable/predictable and/or can be measured with the accuracy, then the material could be used to form the thermal sensing component 1161. In some embodiments, both the resistance and the TCR are functions of the dimensions and arrangement of the resistor. Based on the monitored resistance and the known TCR of the resistor, the temperature may be extracted from the known TCR and the changed temperature in the resulting semiconductor structure is sensed/measured. The thermal sensing device 116 may thus be capable of being used in temperature measurements representative of those of one or more power devices/ hot spots.

With continued reference to FIGS. 2D and 2A, the thermal sensing components 1161 may be implemented by one or more 2-terminal device(s) 1161B. The 2-terminal device(s) 1161B may be disposed alongside the conductive layer 1152 and formed by using any suitable deposition process. In some embodiments, the 2-terminal device(s) 1161B is formed at the fourth level (M4) or above the fourth level in the interconnect structure 115. The respective 2-terminal device 1161B may include a 2D material layer 1161B1 and one or more terminal(s) 1161B2 connected to the 2D material layer 1161B1. In the illustrated embodiment, two terminals 1161B2 are disposed at opposing lateral sides of the 2D material layer 1161B1. The terminals 1161B2 may have a different number and arrangement than shown. The terminals 1161B2 may be physically and electrically connected to the conductive features 1162f and/or the conductive vias 1161v. The terminals 1161B2 may include one or more conductive material(s) such as Co, W, Cu, Ti, Ta, Al, a combination thereof, or other suitable metallic materials.

The 2D material layer 1161B1 may include MoS₂, WS₂, MoSe₂, WSe₂, MoTe₂, the like, a combination thereof, etc. In some embodiments, the thickness of the 2D material layer 1161B1 measured in the direction D3 may be in a range of about 1μm and about 100μm. In some embodiments, the thickness of the 2D material layer 1161B1 is less than the thickness of the respective terminal 1161B2 and/or less than the thickness of the conductive layer 1152 at the same level height. The length of the 2D material layer 1161B1 may be in a range of about 1μm and about 10μm. The width of the 2D material layer 1161B1 may be in a range of about 1μm and about 10μm. The total resistance of the 2D material layer 1161B1 may be in a range of about 10kΩ and 10MΩ. In some embodiments, the 2D material layer 1161B1 has a TCR of about 0.2-2%/K. The 2D material layer 1161B1 may have other suitable values, depending on product and circuit requirements. Based on the monitored resistance and the known TCR of the 2D material layer 1161B1, the temperature may be extracted from the known TCR and the changed temperature in the resulting semiconductor structure is determined or sensed. The thermal sensing device 116 may be capable of being used in temperature measurements (e.g., temperature-dependent resistance measurements).

The aforementioned structures to implement the thermal sensing components 1161 are given for illustrative purposes. Various types of thermal sensing components 1161 are within the contemplated scope of the present disclosure. Thermal sensing component 1161 may have a feature varying according to its temperature, and the thermal sensing components 1161 may be close enough to the devices/regions/paths to be monitored/sensed. The thermal sensing components 1161 may be arranged in the interconnect structure 115 at different levels to monitor the temperatures at different depths in the resulting semiconductor structure (see FIG. 6). For example, the thermal sensing components 1161 are arranged in a manner to create a temperature profile map of the resulting semiconductor structure (see FIG. 6).

Referring to FIG. 3 and with reference to FIG. 2A, a first bonding structure 117 may be formed on the interconnect structure 115. Since the first bonding structure 117 is formed over the front side of the semiconductor substrate 111, the first bonding structure 117 may be viewed as a front-side bonding structure. For example, the first bonding structure 117 includes a first bonding dielectric layer 1171 and one or more first bonding feature(s) 1172 covered by the first bonding dielectric layer 1171. The first bonding dielectric layer 1171 may be formed on the topmost one of the dielectric sublayers (e.g., 1151d) of the dielectric layer 1151. The first bonding dielectric layer 1171 may be a single layer or include a plurality of stacked dielectric sublayers. The material of the first bonding dielectric layer 1171 may include inorganic materials such as silicon oxide, silicon nitride, silicon oxynitride, silicon carbonitride, silicon oxy-carbonitride, or a combination thereof. The first bonding dielectric layer 1171 may be formed by suitable fabrication techniques such as spin-on coating, CVD, ALD, PVD, or the like.

The first bonding feature(s) 1172 may include one or more conductive material(s) such as Cu, Co, W, Ti, Ta, Al, alloy, a combination thereof, or other suitable metallic materials. In some embodiments, the first bonding features 1172 are formed by damascene process (e.g., single damascene and/or dual damascene). The first bonding features 1172 may be or include conductive pad(s), conductive via(s), a combination thereof, etc. The first bonding features 1172 may be electrically connected to the conductive layer 1152. For example, the first bonding features 1172 land on the topmost one of the conductive sublayers (e.g., 1152d) of the conductive layer 1152. In some embodiments, the first bonding features 1172 are electrically isolated from the thermal sensing device 116. In some embodiments, a planarization process (e.g., grinding, CMP, etching, a combination thereof, or the like) is performed on the first bonding structure 117. Following the planarization, the exposed surface 1171t of the first bonding dielectric layer 1171 and the exposed surface 1172t of the first bonding feature 1172 may be substantially leveled (or coplanar), within process variations. The exposed surfaces 1171t and 1172t may be collectively viewed as a bonding surface 117t of the first bonding structure 117.

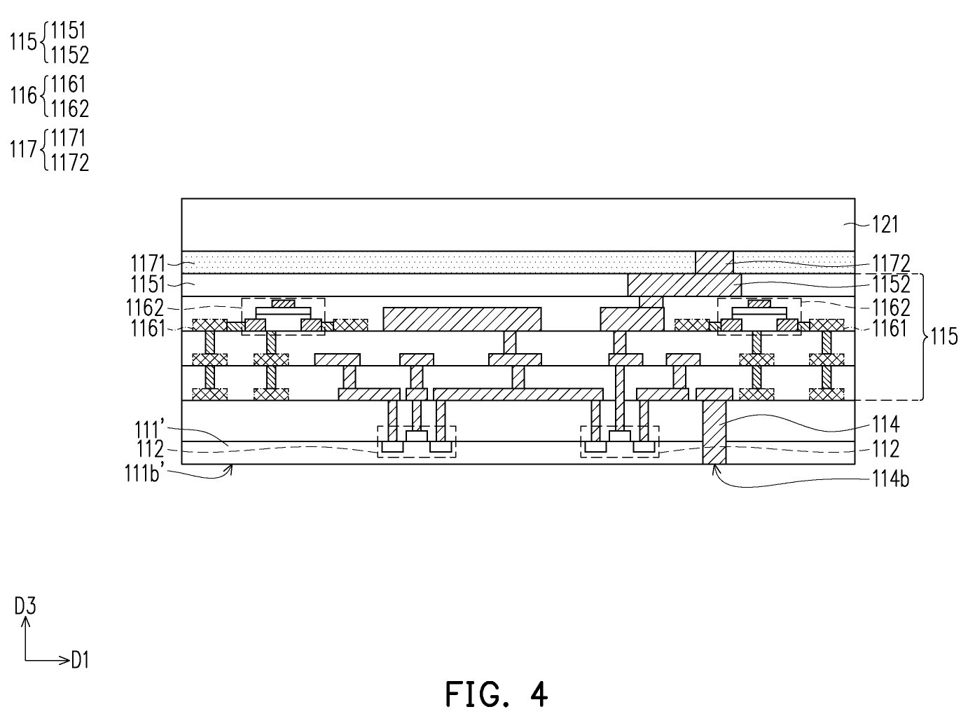

Referring to FIG. 4 and with reference to FIG. 3, a thinning process (e.g., grinding, CMP, etching, a combination thereof, etc.) may be performed on the back side of the semiconductor substrate 111. After the thinning process, at least a portion of the second end 114b of the respective through via 114 may be accessibly exposed from the back side 111b’ of the semiconductor substrate 111’. Since the through via 114 penetrates through the semiconductor substrate 111’, the through via 114 may be referred to as a through substrate via (TSV) 114 according to some embodiments. In some embodiments, a carrier 121 is disposed on the first bonding structure 117. For example, the carrier 121 is bonded to the bonding surface 117t of the first bonding structure 117. In some embodiments, the carrier 121 is a temporary carrier that is used to support the underlying structure during processing (e.g., a thinning process, a bonding process, a singulation process, etc.), and the temporary carrier may be removed once the bonding process is finished. In some embodiments, the carrier 121 provides mechanical and structural support in the resulting semiconductor structure. The carrier 121 may include any suitable material that is rigid enough to provide support for the underlying structure. In some embodiments, the carrier 121 includes one or more thermally conductive material(s) for facilitating thermal dissipation from the underlying structure to the external environment or the overlying structure (if present). For example, the carrier 121 includes silicon (e.g., bulk silicon), metal (e.g., steel), glass, ceramic, combinations thereof, multi-layers thereof, or the like. The bonding of the carrier 121 may be performed prior to the thinning process of the semiconductor substrate 111. Alternatively, the carrier 121 is bonded to the first bonding structure 117 after thinning the semiconductor substrate 111.

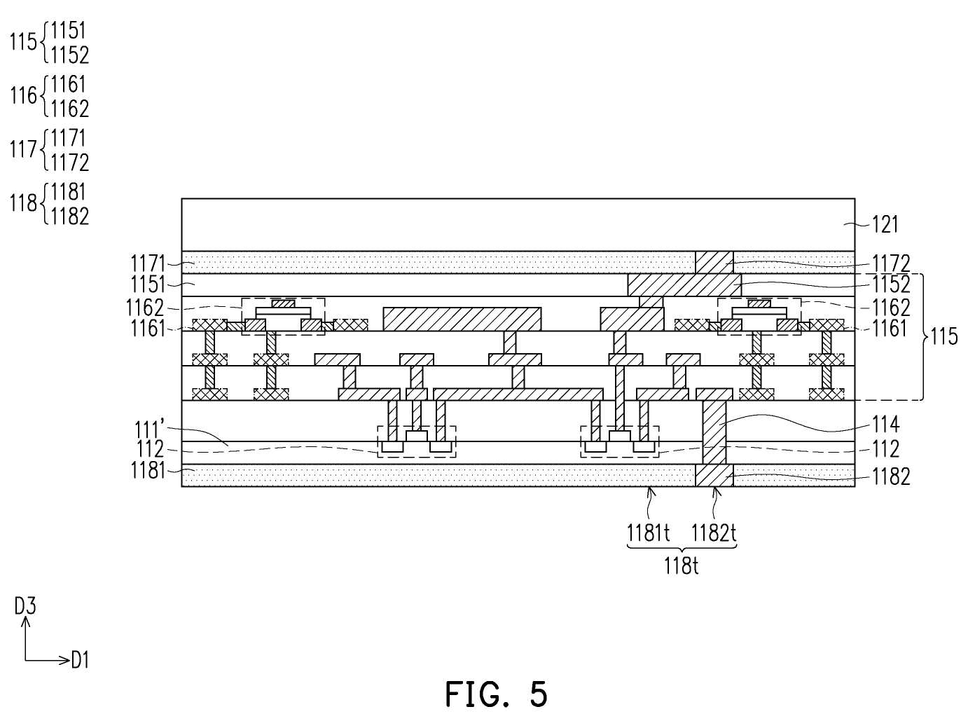

Referring to FIG. 5 and with reference to FIG. 4, a second bonding structure 118 may be formed on the TSVs 114 and the semiconductor substrate 111’. Since the second bonding structure 118 is formed on the back side of the semiconductor substrate 111’, the second bonding structure 118 may be viewed as a backside bonding structure. The second bonding structure 118 may include a second bonding dielectric layer 1181 and one or more second bonding feature(s) 1182 covered by the second bonding dielectric layer 1181. The second bonding dielectric layer 1181 may be formed on the back side 111b’ of the semiconductor substrate 111’. The material of the second bonding dielectric layer 1181 may be similar to that of the first bonding dielectric layer 1171. The second bonding features 1182 may land on the second ends 114b of the TSVs 114 and may be electrically connected to the interconnect structure 115 through the TSVs 114. The material of the second bonding features 1182 may be similar to that of the first bonding features 1172. In some embodiments, a planarization process (e.g., grinding, CMP, etching, a combination thereof, or the like) is performed on the second bonding structure 118. Following the planarization, the exposed surface 1181t of the second bonding dielectric layer 1181 and the exposed surfaces 1182t of the second bonding features 1182 may be substantially leveled (or coplanar), within process variations. The exposed surfaces 1181t and 1182t may be collectively viewed as a bonding surface 118t of the second bonding structure 118.

Referring to FIG. 6 and with reference to FIG. 5, the structure shown in FIG. 5 may be bonded to another structure which is similar to the structure illustrated in FIG. 5 to form a semiconductor structure 10. The semiconductor structure 10 may include a first tier T1 and the second tier T2 stacked upon and bonded to the first tier T1. It should be noted that the semiconductor structure 10 including two tiers is shown for illustrative purposes, and the semiconductor structure may include more than two tiers stacked upon one another according to some embodiments. The second tier T2 may be the structure except the carrier 121 in FIG. 5. The first tier T1 may be similar to the second tier T2. The difference between the first and second tiers T1 and T2 may include that the first tier T1 may not (or may include TSV), the semiconductor substrate 111 of the first tier T1 may not (or may) be thinned down, the thermal sensing device 116 in the first tier T1 may (or may not) be arranged in a different manner than the thermal sensing device 116 in the second tier T2. In some embodiments, each of the first and second tiers T1 and T2 includes one or more thermal sensing device(s) 116 for sensing temperature. Alternatively, one of the first and second tiers T1 and T2 includes the thermal sensing device 116 and the other one of the first and second tiers T1 and T2 is free of thermal sensor.

In some embodiments, the aforementioned steps described in FIGS. 1, 2A, 3, 4 and 5 may be repeated to form a plurality of tiers to be bonded. The bonding of the tiers may involve the wafer-to-wafer bonding, the die-to-wafer bonding, the die-to-die bonding or the like. In some embodiments where the die-to-wafer bonding or die-to-die bonding will be performed, the structure shown in FIG. 5 may be singulated to form a plurality of dies before the bonding. In some embodiments, the bonding process includes at least the following steps. For example, surface preparation (e.g., cleaning, activation, a combination thereof, etc.) for the bonding surface 118t of the second tier T2 and the bonding surface 117t of the first tier T1 may be performed. After the surface preparation, the second tier T2 may be substantially aligned with the first tier T1. For example, each of the second bonding features 1182 of the second tier T2 may be substantially aligned with the corresponding first bonding features 1172 of the first tier T1. The bonding surface 118t of the second bonding structure 118 of the second tier T2 may then be in contact with the bonding surface 117t of the first bonding structure 117 of the first tier T1.

After bringing the second tier T2 to be in contact with the first tier T1, the bonding process may be performed. For example, the bonding process includes thermal treatment for dielectric bonding and thermal annealing for conductor bonding. After the thermal annealing, the first bonding dielectric layer 1171 of the first tier T1 may be fused to the second bonding dielectric layer 1181 of the second tier T2, and the first bonding features 1172 of the first tier T1 may be bonded to the second bonding features 1182 of the second tier T2. The bonds at the bonding interface IF1 of the first tier T1 and the second tier T2 may include dielectric-to-dielectric bonds (e.g., oxide-to-oxide bonds), metal-to-metal bonds (e.g., copper-to-copper bonds), metal-to-dielectric bonds (e.g., copper-to-oxide bonds), any combinations thereof, and/or the like. The bonding interface IF1 may be substantially planar and/or flat. The first and second bonding features (1172 and 1182) may be pad-to-pad bonding, via-to-via bonding, or via-to-pad bonding, depending on product requirements.

With continued reference to FIG. 6, the bonding of the semiconductor structure 10 may be viewed as a face-to-back bonding, where the first bonding structure 117 of the first tier T1 is bonded to the second bonding structure 118 of the second tier T2. In some other embodiments, a face-to-face bonding (e.g., the first bonding structure 117 of the first tier T1 is bonded to first bonding structure 117 of the second tier T2) or back-to-back bonding (e.g., the second bonding structure 118 of the first tier T1 is bonded to the second bonding structure 118 of the second tier T2) may be applied depending on product design. It should be appreciated that while the bonding has been described to connect the second tier T2 to the first tier T1, alternative connection schemes are also possible, with corresponding adaptations to the bonding interface.

Still referring to FIG. 6, the semiconductor structure 10 may include a heat-dissipating component 122 disposed on the carrier 121. The heat-dissipating component 122 may be formed from a material with high thermal conductivity, such as steel, stainless steel, copper, the like, combinations thereof, or any material having good thermal conductivity for heat spreading mechanism. In some embodiments, the heat-dissipating component 122 is coated with another metal. The heat-dissipating component 122 may be a single contiguous material or may include multiple pieces having the same or different materials. The heat-dissipating component 122 may be or include a heat sink, a heat spreader, a lid, etc. The heat-dissipating component 122 in FIG. 6 is given for illustrative purposes, and the heat-dissipating component 122 may be provided in any suitable form (e.g., a plate-form, a fin-form, etc.).

In some embodiments, the heat-dissipating component 122 is attached to the carrier 121 by an adhesive (not individually shown). The adhesive may be epoxy, glue, or the like, and may include a thermally conductive material or any material which is capable of transferring heat. The heat-dissipating component 122 may be thermally coupled to the underlying structure through the adhesive. The adhesive may be deposited at the intended location(s) to allow the heat-dissipating component 122 to be attached onto the carrier 121. Alternatively, the carrier 121 is omitted, and the heat-dissipating component 122 is directly coupled to the second tier T2. In other embodiments, the heat-dissipating component 122 is omitted. It should be noted that the heat-dissipating component 122 may be any type of heat spreading mechanism which meets heat dissipation requirements of the semiconductor structure 10. In some embodiments, a singulation process is performed to dice the bonded structure into a plurality of semiconductor structures 10. The respective semiconductor structure 10 may then be packaged or coupled to another package component, depending on demands.

Embodiments may have one or a combination of the following features and/or advantages. Embodiments of the thermal sensing device 116 may be integrated in semiconductor circuitry manufactured by BEOL processes. The thermal sensing device 116 may either be routed to front-end devices (e.g., the first devices 112) for the measurement of temperature, or the measurement circuit may be built on the back-end using the back-end devices (e.g., the second devices 1162). The thermal sensing device 116 may include the control circuit configured to receive the temperature-dependent parameters and generate control signals. The control circuit including the second devices 1162 may be formed of BEOL-compatible materials for fast and accurate temperature sensing. The thermal sensing device 116 may include thermal sensing components 1161 thermally coupled to devices/regions/paths to be monitored and implemented by resistors, 2-terminal devices, a combination thereof, the like, etc. The thermal sensing device 116 may be formed of BEOL-compatible materials and may have a material whose resistance is dependent on temperature. The feedback circuit connected to the thermal sensing device 116 may be configured to dynamically control power input to the corresponding tier of the semiconductor structure 10. For example, making the adjustment to the circuit operation is made in response to sensed/measured temperatures to reduce or avoid an overheating condition, thereby enhancing performance and reliability of the semiconductor structure 10.

Placement of the thermal sensing device 116 may be flexible. In the semiconductor structure 10, more than one of the thermal sensing devices 116 may be placed at locations throughout the semiconductor structure 10. For example, the thermal sensing devices 116 are placed at intervals over the area of the interconnect structure 115 to obtain a thermal profile of the corresponding tier. The thermal sensing devices 116 may be placed proximate temperature sensitive circuits/devices/regions/paths to get highly accurate temperature readings at sensitive areas. Multiple thermal sensing components 1161 arranged in an array and in different layers in the semiconductor structure 10 may increase accuracy of the temperature sensing device 116 and create 3D temperature profile mapping that enables accurate temperature sensing.

According to some embodiments, a semiconductor structure includes a first interconnect structure disposed over a first semiconductor substrate, thermal sensors embedded in the first interconnect structure and sensing temperature variations in the semiconductor structure, and a first bonding structure disposed on and electrically coupled to the first interconnect structure. The thermal sensors are electrically isolated from conductive features of the first interconnect structure and the first bonding structure.

According to some embodiments, a semiconductor structure includes a hot spot region over a semiconductor substrate, an interconnect structure over the semiconductor substrate, and thermal sensors embedded in different levels of the interconnect structure. The thermal sensors include first sensors monitoring a temperature change of the hot spot region and second sensors monitoring a temperature change of a region outside the hot spot region, and the first sensors are arranged in a denser manner than the second sensors.

According to some embodiments, a manufacturing method of a semiconductor structure includes: forming an interconnect structure over a semiconductor substrate through BEOL processes; forming thermal sensors over the semiconductor substrate and in the interconnect structure, wherein the thermal sensors are formed of materials compatible with the BEOL processes; and forming a bonding structure over the interconnect structure, wherein the thermal sensors are electrically isolated from conductive features of the interconnect structure and the bonding structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor structure, comprising:
forming a first interconnect structure over a first semiconductor substrate through back-end-of-line (BEOL) processes;
forming thermal sensors over the first semiconductor substrate and in the first interconnect structure, wherein the thermal sensors are formed of materials compatible with the BEOL processes; and
forming a first bonding structure over the first interconnect structure, wherein the thermal sensors are electrically isolated from conductive features of the first interconnect structure and the first bonding structure.

2. The manufacturing method of claim 1, further comprising:
forming first transistors on the first semiconductor substrate through front-end-of-line (FEOL) processes, wherein the first interconnect structure is electrically coupled to the first transistors; and
forming second transistors in the first interconnect structure through the BEOL processes, wherein the second transistors are included in the thermal sensors.

3. The manufacturing method of claim 1, wherein the step of forming the thermal sensors comprises:
forming metal resistors at different levels of the first interconnect structure.

4. The manufacturing method of claim 1, wherein the step of forming the thermal sensors comprises:
forming thermal sensing components at different levels of the first interconnect structure, wherein the thermal sensing components comprise a two dimensional (2D) material layer.

5. The manufacturing method of claim 1, wherein the step of forming the thermal sensors comprises:
forming a two-terminal device in the first interconnect structure, wherein the two-terminal device comprises a 2D material layer and two terminals disposed at opposing sides of the 2D material layer; and
forming a transistor in the first interconnect structure to be electrically coupled to the two-terminal device.

6. The manufacturing method of claim 5, wherein the step of forming the transistor in the first interconnect structure comprises:
forming a channel layer, wherein a material of the channel layer has a higher temperature coefficient of resistance than a conductive material of the conductive features of the first interconnect structure; and
forming source/drain contacts at opposing sides of the channel layer, wherein the source/drain contacts are in lateral contact with the two-terminal device.

7. The manufacturing method of claim 1, further comprising:
planarizing the first bonding structure, wherein the first bonding structure comprises a first bonding dielectric layer and a first bonding connector covered by the first bonding dielectric layer, and bonding surfaces of the first bonding dielectric layer and the first bonding connector are substantially leveled.

8. The manufacturing method of claim 7, further comprising:
forming a second bonding structure over a second semiconductor substrate; and
bonding the second bonding structure to the first bonding structure through metal-to-metal bonding and dielectric-to-dielectric bonding.

9. The manufacturing method of claim 1, further comprising:
forming a through via in the first semiconductor substrate before the step of forming the first interconnect structure over the first semiconductor substrate;
thinning the first semiconductor substrate to expose the through via; and
forming a second bonding structure on a thinned surface of the first semiconductor substrate and an exposed surface of the through via.

10. The manufacturing method of claim 1, wherein:
the step of forming the first interconnect structure comprises:
forming conductive patterns on a first dielectric layer and a second dielectric layer formed over the first dielectric layer; and
the step of forming the thermal sensors comprises:
forming first thermal sensing components on the first dielectric layer and second thermal sensing components on the second dielectric layer.

11. A manufacturing method of a semiconductor structure, comprising:
forming active devices on a first side of a first semiconductor substrate;
forming a first interconnect structure over the first side of the first semiconductor substrate;
forming first control transistors in the first interconnect structure; and
forming first thermal sensing components in the first interconnect structure, wherein the first thermal sensing components and the first control transistors are electrically coupled and form first thermal sensors, and the first thermal sensors are distributed at different levels of the first interconnect structure.

12. The manufacturing method of claim 11, further comprising:
disposing a carrier over the first interconnect structure;
thinning a second side of the first semiconductor substrate opposite to the first side, wherein the carrier serves as a support during the step of thinning the second side of the first semiconductor substrate; and
forming a first bonding structure on the second side of the first semiconductor substrate after the step of thinning the second side of the first semiconductor substrate.

13. The manufacturing method of claim 12, further comprising:
forming a second interconnect structure over a second semiconductor substrate;
forming second control transistors in the second interconnect structure;
forming second thermal sensing components in the second interconnect structure, wherein the second thermal sensing components and the second control transistors are electrically coupled and form second thermal sensors;
forming a second bonding structure on the second interconnect structure; and
bonding the first bonding structure to the second bonding structure.

14. The manufacturing method of claim 13, wherein:
the step of forming the first bonding structure on the second side of the first semiconductor substrate comprises:
planarizing a first bonding surface of the first bonding structure, wherein the first bonding surface comprises surfaces of a first bonding dielectric layer and a first bonding connector substantially leveled with each other;
the step of forming the second bonding structure on the second interconnect structure comprises:
planarizing a second bonding surface of the second bonding structure, wherein the second bonding surface comprises surfaces of a second bonding dielectric layer and a second bonding connector substantially leveled with each other; and
the method further comprises:
bonding the first bonding dielectric layer to the second bonding dielectric layer and bonding the first bonding connector to the second bonding connector.

15. The manufacturing method of claim 12, further comprising:
disposing a heat-dissipating component on the carrier.

16. The manufacturing method of claim 11, wherein the step of forming the first thermal sensing components in the first interconnect structure comprises:
forming a 2D material layer on a dielectric layer of the first interconnect structure; and
forming terminals at lateral sides of the 2D material layer and on the dielectric layer of the first interconnect structure.

17. The manufacturing method of claim 16, wherein the step of forming the first control transistors in the first interconnect structure comprises:
forming a channel layer on the dielectric layer of the first interconnect structure;
forming source/drain contacts at lateral sides of the channel layer and on the dielectric layer of the first interconnect structure, wherein the terminals are in lateral contact with the source/drain contacts.

18. A manufacturing method of a semiconductor structure, comprising:
performing FEOL processes to form first transistors on a semiconductor substrate; and
performing BEOL processes to form an interconnect structure over the semiconductor substrate and thermal sensors in the interconnect structure, wherein the thermal sensors comprise second transistors and thermal sensing components coupled to the second transistors, and the thermal sensors are electrically isolated from conductive features of the interconnect structure.

19. The manufacturing method of claim 18, wherein:
the step of forming the interconnect structure over the semiconductor substrate comprises:
forming a first dielectric layer and a second dielectric layer over the first dielectric layer;
the step of forming the thermal sensors in the interconnect structure comprises:
forming a first set of the thermal sensing components on the first dielectric layer; and
forming a second set of the thermal sensing components on the second dielectric layer.

20. The manufacturing method of claim 18, further comprising:
forming a first bonding structure on the interconnect structure comprising:
forming a first bonding connector in a first bonding dielectric layer;
planarizing bonding surfaces of the first bonding dielectric layer and the first bonding connector; and
bonding a second bonding structure to the first bonding structure.
